(19) United States
(12) Patent Application Publication
(10) Pub. No.: US 2023/0135349 A1
(43) Pub. Date: May 4, 2023

(54) MULTI-ROW HEIGHT COMPOSITE CELL WITH MULTIPLE LOGIC FUNCTIONS

(71) Applicant: Texas Instruments Incorporated, Dallas, TX (US)

(72) Inventors: Rakesh DIMRI, Bengaluru (IN); Badarish Mohan SUBBANNAVAR, Bengaluru (IN); Somasekar J., Bengaluru (IN)

(21) Appl. No.: 17/514,856

(22) Filed: Oct. 29, 2021

(51) Int. Cl. H01L 27/118

(52) U.S. Cl. CPC H01L 27/11807; H01L 2027/11824; H01L 2027/11825; H01L 2027/11881

(57) ABSTRACT

An IC includes first-third power rails. The first-third power rails are located along corresponding first-third centerlines spaced apart by the same distance. A plurality of first logic cells is in first and second width that is an integer multiple of a unit width and a first semiconductor structure that includes multiple transistors. For each first logic cell in the first row, the first semiconductor structure is located entirely between the first and second centerlines. For each first logic cell in the second row, the first semiconductor structure is located entirely between the first and third centerlines. A multi-height logic cell includes a second height that is greater than the first height, and a second width that is at least the unit width. The second semiconductor structure includes at least two transistors. The second semiconductor structure is partially between the first and second centerlines and between the first and third centerlines.

### CROSS-REFERENCE TO RELATED APPLICATIONS

This application is related to U.S. patent application Ser. No. 17/463,115, filed Aug. 31, 2021, and to U.S. patent application Ser. No. 17/514,580 (TI docket No. T91946US01) filed on even date herewith, each of which is incorporated herein by reference in its entirety.

### BACKGROUND

Software tools are available that, based on a higher-level digital design, select logic cells to convert the higher-level digital design into a lower-level, transistor-level implementation. Logic cells include transistors configured to perform logic functions such as inverters, NAND gates, NOR gates, etc. The transistors of logic cells perform the logic functions at a particular output drive current capacity. Some logic cells are capable of higher output drive current than other cells. A higher output drive current logic cell is generally a higher performance logic cell than a lower output drive current logic cell. An example of performance includes the propagation delay through the cell. A higher performance logic cell has a lower propagation delay through the cell than a lower performance logic cell. Any given logic function (NAND, NOR, etc.) may have multiple performance logic cells (two, three, etc.) for that particular logic function to accommodate the varying needs of the application. Conventionally, logic cells in a digital library have a standard height with varying widths.

### SUMMARY

In one example, an integrated circuit (IC) includes first, second and third power rails located over a semiconductor substrate. The first, second and third power rails are located along corresponding first, second and third centerlines spaced apart by the same distance. A plurality of first logic cells is arranged over the semiconductor substrate in first and second rows. The first row is separated from the second row by the first centerline. Each of the first logic cells includes a first height and a first width that is an integer multiple of a unit width and a first semiconductor structure that includes at least two transistors and interconnections. For each first logic cell in the first row, the first semiconductor structure is located entirely between the first and second centerlines, and for each first logic cell in the second row, the first semiconductor structure is located entirely between the first and third centerlines. A multi-height logic cell is arranged over the semiconductor substrate and includes a second height that is greater than the first height, a second width that is at least the unit width. The second semiconductor structure includes at least two transistors and interconnections. The second semiconductor structure is located partially between the first and second centerlines and is partially between the first and third centerlines.

### BRIEF DESCRIPTION OF THE DRAWINGS

For a detailed description of various examples, reference will now be made to the accompanying drawings in which:

FIG. 1 is a plan view of a logic cell in accordance with an example.

FIG. 2 is a circuit schematic of the logic cell of FIG. 1.

FIG. 3 is a plan view of another logic cell capable of a higher drive current than the logic cell of FIG. 1 in accordance with an example.

FIG. 4 is a plan view of yet another logic cell capable of a higher drive current than the logic cell of FIG. 2 in accordance with an example.

FIG. 5 is a circuit schematic of the logic cell of FIG. 4.

FIG. 6 is a plan view of an integrated circuit having multiple rows, each row including multiple logic cells in accordance with an example.

FIG. 7 is a plan view of a multi-height row, composite logic cell in accordance with an example.

FIG. 8 is a plan view of an integrated circuit having multiple rows, each row including multiple logic cells and at least one of the cells includes the multi-height row, composite logic cell of FIG. 7 in accordance with an example.

FIG. 9 is a plan view of integrated circuit in which the multi-height row, composite logic cell spans the combined height of three rows.

FIG. 10 is a flow chart depicting an example method of forming an integrated to include a multi-height row, composite logic cell in accordance with an example.

The same reference number is used in the drawings for the same or similar (either by function and/or structure) features.

### DETAILED DESCRIPTION

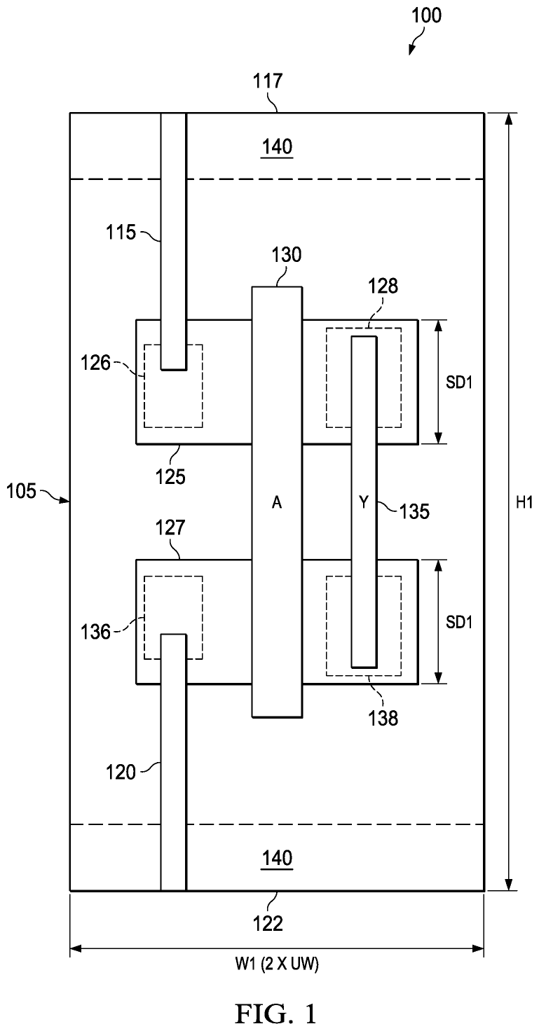

FIG. 1 is a plan view of an example logic cell 100 of an integrated circuit (100). The example logic cell 100 has two transistors and is characterized by a low-drive logic cell. References to “low” or “high” current drive logic cells does not imply any particular current level, only that a low current drive logic cell has a lower current capability than a high current drive logic cell.

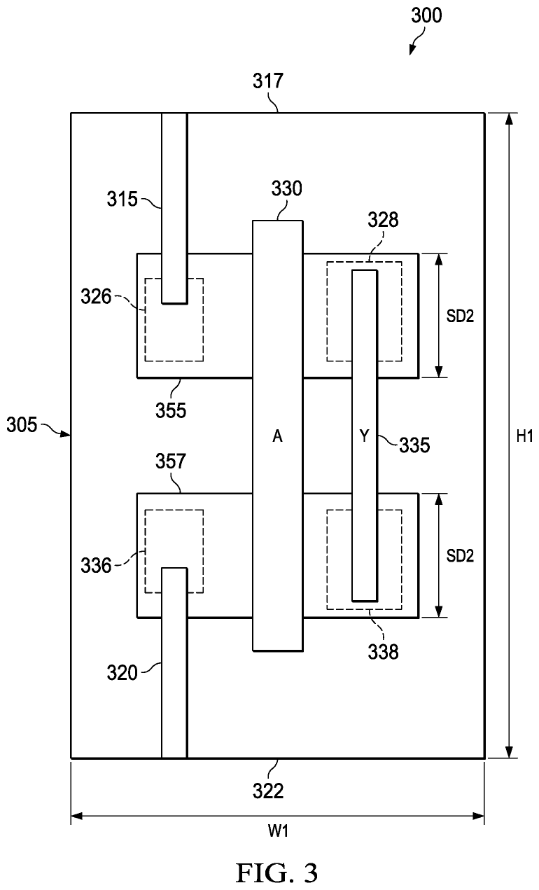

The example low-drive logic cell 100 of FIG. 1 represents, for example, 0.5× (or fifty percent) of the output drive current capacity of the high-drive logic cell 300 of FIG. 3, described below. The low-drive logic cell 100 has a height H1 and a width W1. The height H1 is a standard cell that defines the height of low and high-drive logic cells. In one example, H1 is 2.5 micrometers (microns). The width, however, may vary from logic cell to logic cell. A “unit width” (UW) defines a standard width measurement of, for example, 0.5 microns. In the example of FIG. 1, the width W1 of logic cell 100 is double the unit width (2×UW) and accordingly W1 is 1.0 microns.

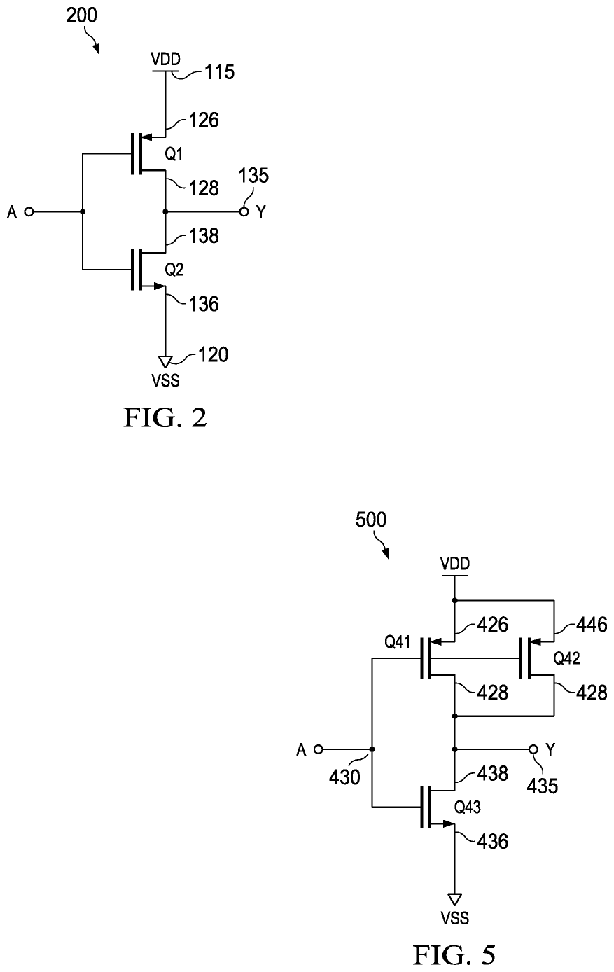

The transistors of the logic cell 100 of FIG. 1 are configured as an inverter, which is schematically shown in FIG. 2. The inverter 200 includes a P-type couple to metal-oxide semiconductor field effect transistor (PMOS transistor) Q1 and N-type metal-oxide semiconductor field effect transistor (NMOS transistor) Q2 (as well as interconnections, for example, metal connections). Transistor Q1 has a source 126 and a drain 128. Transistor Q2 has a source 136 and a drain 138. The source 126 of transistor Q1 is coupled to a first power rail (e.g., a non-zero supply voltage, VDD) by a trace 115, and the source 136 of transistor Q2 is coupled a second power rail (e.g., ground (VSS)) by a trace 120. While shown in a polysilicon level, the traces 115, 120 may be in any interconnect level. While not explicitly shown, the power rails 115, 120 may be located in a metal layer above the low-drive logic cell 100 such that the side 117 is at about parallel to and at a midpoint of the power rail 115 and the side 122 is at about parallel to and at a midpoint of the power rail 120. The drains 128 and 138 of transistors Q1 and Q2 are coupled together at an output node Y (labeled 135). A polysilicon (or other suitable material) trace 130 acts as the gate of the transistors Q1 and Q2 and a local interconnect between the gates, and is an input node A of the logic cell 100. The gates of transistors Q1 and Q2 are coupled together at an input node A (labeled 130). The signal on the output node Y is the logical inverse of the signal on the input node A. For example, the signal on the output node Y is a logic high responsive to the signal on the input node A being logic low and vice versa.

Referring again to FIG. 1, the low-drive logic cell 100 includes the power rails 115 and 120 along opposing sides 117 and 122, respectively, defined by the longitudinal axis along the height H1. Power rail 115 (configured to receive VDD) is along the side 117, and power rail 120 (configured to receive VSS) is along the opposing side 122. The low-drive logic cell 100 includes a first transistor source-drain region 125, and a second transistor source-drain region 127. Source-drain region 125 includes the source 126 and the drain 128 of PMOS transistor Q1. Similarly, source-drain region 127 includes the source 136 and the drain 138 of NMOS transistor Q2.

FIG. 3 is an example of a digital logic cell 300 that also implements an inverter but at a higher output drive current than the digital logic cell 100 of FIG. 1. Logic cell 300 includes a first power rail 315 (e.g., VDD) along one side 317, and a second power rail 320 (e.g., VSS) along the opposing side 322. Logic cell 300 includes a first transistor source-drain region 355, and a second transistor source-drain region 357. The source-drain region 355 includes a source 326 of a first PMOS transistor, and a drain 328 of the same PMOS transistor. The source 326 is coupled to the power rail 115 (e.g., VDD) at a metal layer. The source-drain region 357 includes a source 336 of a second NMOS transistor, and a drain 338 of the same NMOS transistor. The source 336 is coupled to the power rail 320 (e.g., VSS) at a metal layer. The drains 328 and 338 of the PMOS and NMOS transistors are coupled together by a metal interconnect layer to provide the output 335 (Y). A polysilicon (or other suitable material) trace 330 acts as the gate over the source/drain region 355 and the source/drain region 357, as a local interconnect between the gates, and is an input node A of the logic cell 100.

The width of the source-drain regions 125 and 127 of the low-drive logic cell 100 of FIG. 1 is SD1. The width of the source-drain regions 355 and 357 of the high-drive logic cell 300 of FIG. 3 is SD2. SD2 is larger than SD1 and thus the on-resistance of the PMOS and NMOS transistors comprising logic cell 300 is smaller than the on-resistance of the PMOS and NMOS transistors comprising logic cell 100. Accordingly, the output current drive strength of logic cell 300 is greater than the output current drive strength of logic cell 100. Further, the PMOS and NMOS transistors of logic cell 300 have a faster switching speed than the transistors of logic cell 100, and thus the high-drive logic cell 300 has a smaller propagation delay than the low-drive logic cell 100. For these and other reasons, high-drive logic cell 300 implements a higher performance inverter than the low-drive logic cell 100.

The height of high-drive logic cell 300 is H1—the same height as for the low-drive logic cell 100. While the widths of different logic cells can vary, in the example of FIG. 3, the width of logic cell 300 is W1—the same width as logic cell 100. Thus, the overall size and area of logic cells 100 and 300 are the same. However, because the source-drain regions 125 and 127 of logic cell 100 have a smaller width (SD1) and the widths of source-drain regions 355 and 357 of logic cell 300, the source-drain regions 355 and 357 of logic cell 300 occupies more of the logic cell's area than for source-drain regions 125 and 127 of logic cell 100. Accordingly, logic cell 100 has a larger unused area than logic 300. The unused area of logic cell 100 is generally denoted by reference numeral 140. Unused area 140 is the area on the semiconductor substrate on which the transistors are formed between the sources of the transistors and the respective upper and lower boundaries (sides 117 and 122) of the logic cell.

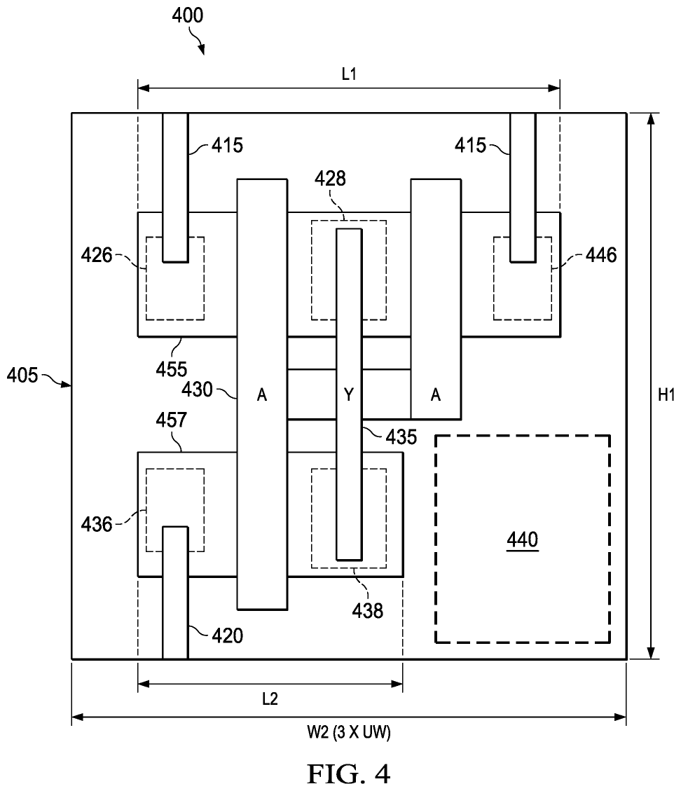

FIG. 4 is a plan view of another logic cell 400 that also implements a logic inverter function. FIG. 5 is an electrical circuit schematic of logic cell 400. The inverter implemented in FIG. 4 includes two PMOS transistors Q41 and Q42 and one NMOS transistor Q43. PMOS transistors Q41 and Q42 are connected in parallel—sources 426 and 446 are connected together, drains 428 are connected together (output 435, Y), and gates are implemented by a polysilicon (or other suitable material) trace 430 that also connects the gates together and provides an input A to the logic cell 400. In FIG. 4, the logic cell 400 includes source-drain regions 455 and 457. Source-drain region 455 has the sources 426 and 446 coupled to power rail 415. Source-drain 457 has the source 436 coupled to power rail 420. The drain 428 of source-drain region 455 is coupled via a metal 435 (output Y) to drain 438 of source-drain region 457. Because two PMOS transistors Q41 and Q42 are coupled in parallel, all else being equal, the inverter of FIGS. 4 and 5 implements higher drive current and thus lower propagation delay for an input switching from a logic high state to a logic low state (at which time both PMOS transistors turned on) than if only one PMOS was used as in the examples of FIGS. 1 and 3.

The width of source-drain region 455, which is shared by the two PMOS transistors) is L1. The width of source-drain region 457 of the NMOS transistor is L2. Because, source-drain region 455 is part of two transistors but the source-drain region 457 is for only a single transistor, L1 is larger than L2. The width W2 of the logic cell 400 is defined largely by the width L1 of the source-drain region 455. The width W2 of the logic cell 400 is 3×UW in this example due L1 being larger than L2. Accordingly, the logic cell 400 includes unused space 440 adjacent source-drain region 457 and below source-drain region 455 as shown in FIG. 4. The height of the logic cell 400 is H1, which is the same height as logic cells 100 and 300.

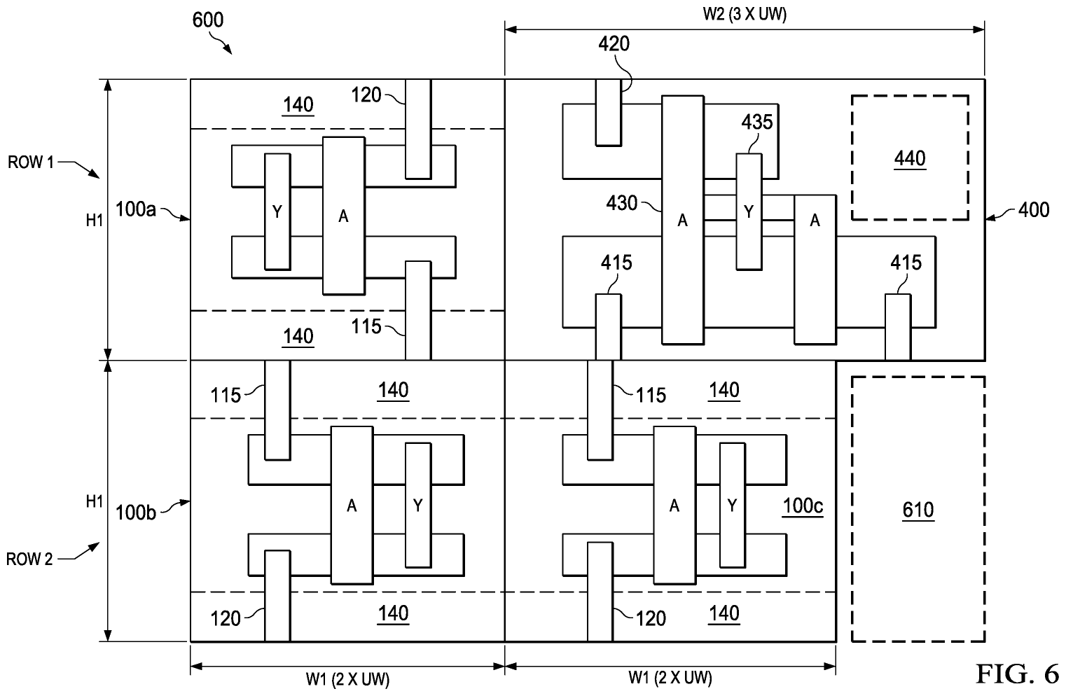

FIG. 6 shows an example of an IC 600 which includes multiple rows of logic cells. Two of the rows of the IC 600 are shown and labeled as ROW1 and ROW2. IC 600 may include one or more additional rows of logic cells as well. ROW1 includes logic cells 100a and 400, with logic cell 400 being a mirror image in the plan view of FIG. 6 from its representation in FIG. 4. ROW2 includes two of the logic cells 100b and 100c. Logic cells 100a, 100b, and 100c are generally identical instances of logic cell 100 described above. Unused spaces 140 and 440 are shown. Because the width W2 of logic cell 400 is larger than width W1 of logic cell 100 potentially unusable space 610 is present adjacent the logic cell 100c below logic cell 400 as shown in FIG. 6.

While three instances 100a-100c of the same low-drive logic cell are shown in the example IC 600 of FIG. 6, logic cells 100a-100c need not all be identical instances of the same logic cell. The logic cells identified as 100a-100c are low-drive strength logic cells— lower drive strength than logic cell 400. The particular logic function of any of the lower drive strength logic cells can be an inverter, NAND gate, NOR gate, etc. Similarly, the logic function of the high-drive logic cell 400 can be an inverter, NAND gate, NOR gate, etc. Any two or more of the logic cells shown in FIG. 6 can implement the same logic function. In some embodiments, all three of the logic cells shown in FIG. 6 implement different logic functions.

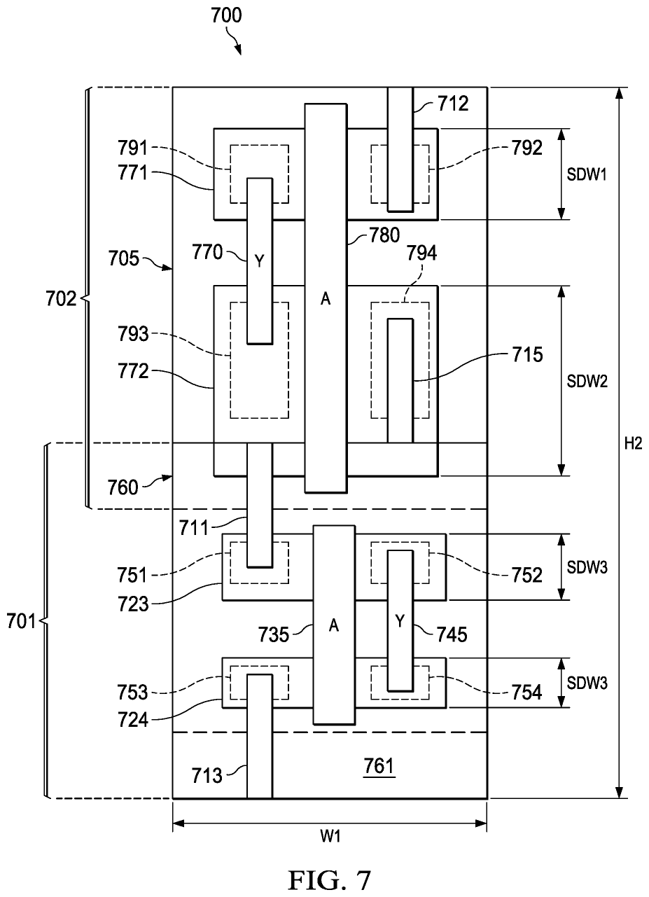

FIG. 7 is a plan view of a multi-height, composite logic cell 700, which includes at least two semiconductor structures, each semiconductor structure implementing a separate logic function (which may be the same or different logic functions from each other). One logic function is implemented as a low drive-strength logic function, and another logic function is implemented as a high drive-strength logic function. The multi-height row, composite logic cell 700 includes a lower portion 701 and an upper portion 702. The upper and lower portions 701 and 702 overlap. The upper portion 702 includes a semiconductor structure that implements at least one high-drive strength logic function. The lower portion 701 includes a separate semiconductor structure that implements at least one low-drive strength logic function. The output current capacity of the semiconductor structure of the upper portion 702 is a larger current capacity than the output current capacity of the semiconductor structure of the lower portion 701. The logic function of the upper portion 702 may be any logic function, for example, inverter, NAND gate, NOR gate, etc. The logic function of the lower portion 701 may be any logic function, for example, inverter, NAND gate, NOR gate, etc. The logic functions of the upper and lower portions may be the same or different.

The lower portion 701 of the multi-height row, composite logic cell 700 may be the same or similar to logic cell 100 of FIG. 1, and thus implements a logic function that is an inverter. The semiconductor structure of the lower portion 701 includes source-drain regions 723 and 724. Source-drain region 723 includes source 751 and drain 752, and source-drain region 724 includes source 753 and drain 754. Drains 7523 and 754 are coupled by way of metal 745 which provides the output Y of the inverter. The gates of the two transistors are implemented by a polysilicon trace 735 that also connects the gates provides the input A for the inverter. The source 751 is coupled to a power rail 711 (e.g., VDD). The source 753 is coupled to the power rail 713 (e.g., VSS).

Regions 760 and 761 above and below the source-drain regions 723 and 724 in the plan view of FIG. 7 illustrate the unused regions noted above (unused areas 140 in FIG. 1). Upper unused region 760, however, is at least partially filled with at least a portion of the semiconductor structure that implements the logic function occupying the upper portion 702 of logic cell 700.

The semiconductor structure of the upper portion 702 of the logic cell 700 includes source-drain regions 771 and 772. Source-drain region 771 includes drain 791 and source 792, and source-drain region 772 includes drain 793 and source 794. Drains 791 and 792 are coupled together by way of metal 770 which provides the output Y of the logic function implemented by the semiconductor structure of the upper portion 702. The gates of the two transistors forming the logic function of the upper portion 702 are implemented by a polysilicon trace 780 that connects the gates and provides the input A for the logic function of the upper portion 702. The source 794 is coupled to the power rail 711 (e.g., VDD). The source 792 is coupled to the power rail 712 (e.g., VSS).

The multi-height row, composite logic cell 700 includes the power rail 711 (e.g., VDD) and power rails 712 and 713. Power rails 712 and 713 may be configured to provide the same voltage (e.g., VSS). While not explicitly shown, the power rail 711 may extend in a metal layer above the midline between the upper side of the upper portion 702 and the lower side of the lower portion 701 (horizontally in the view of FIG. 7). Similarly, the power rail 712 may extend in a metal layer above the upper side of the upper portion 702, and the power rail 713 may extend in a metal layer above the lower side of the lower portion 701.

As explained above, the semiconductor structure implementing the logic function of the lower portion 701 of the multi-height row, composite logic cell 700 has a lower drive strength than the drive strength of the semiconductor structure implementing the logic function of the upper portion 702. Accordingly, assuming the logic functions of the upper and lower portions 702 and 701 are the same (which is not generally the case), the logic function implemented by the logic function in the upper portion 702 of the multi-height row, composite logic cell 700 may have a lower propagation delay than the logic function implemented by the logic function in the lower portion 701. Because the semiconductor structure of the lower portion 701 has a lower drive strength, that portion has the unused areas 760 and 761 as identified above regarding unused areas 140 in the example of FIG. 1. Accordingly, the semiconductor structure of the upper portion 702 can be fabricated with a larger width SDW2 of source-drain region 772 to accommodate the higher drive strength because at least a portion of the source-drain region 772 resides within the otherwise unused area 760 of the lower portion 701. In some other examples, the components of the lower portion 701 could be translated down into the unused area 761 to provide additional area for the components of the upper portion 702 to use.

Notably, the power rail 711, which lies partially over the lower portion 701 and the upper portion 702, may overlie the source-drain region 722 or other components of one or the other of the lower portion 701 and the upper portion 702. In another view, the components of on or the other of the lower portion 701 and the upper portion 702 cross the midline between the upper side of the upper portion 702 and the lower side of the lower portion 701. In conventional cell layout exemplified by the cells 100a and 100b in FIG. 6, the components of neighboring cells are confined to the pitch between neighboring power rails. By allowing components to extend beyond the midline, otherwise unused area in one cell may be productively used by components of the neighboring cell.

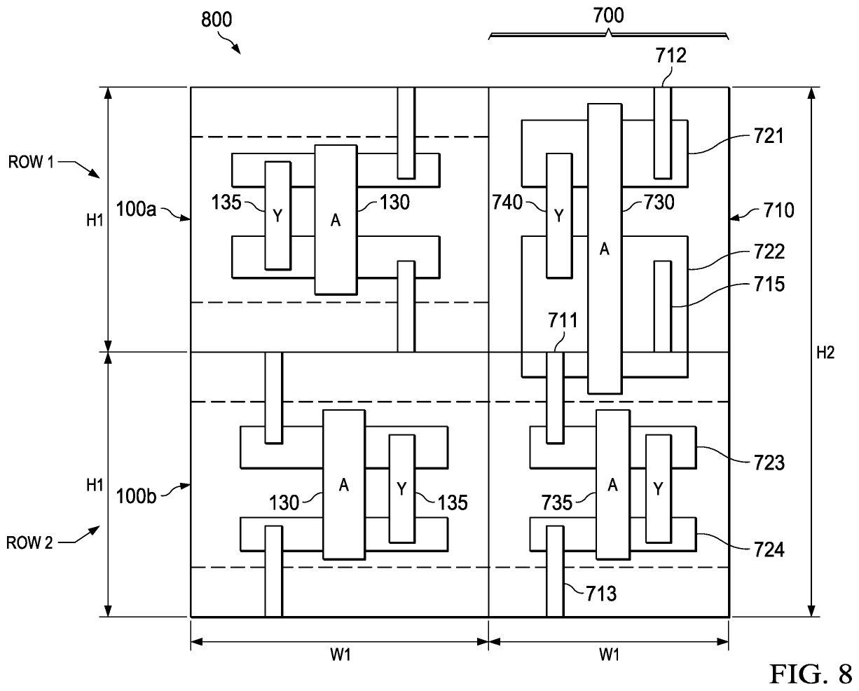

FIG. 8 shows an example of an IC 800 which includes multiple rows of logic cells. Two of the rows of the IC 800 are shown and labeled as ROW1 and ROW2. IC 800 may include one or more additional rows of logic cells as well. ROW1 includes logic cell 100a, with logic cell 100a inverted in the plan view of FIG. 8 from its representation in FIG. 1. ROW2 also includes a logic cell 100b. Logic cells 100a and 100b are generally identical instances of logic cell 100 described above with the exception of the physical inversion. IC 800 also includes an instance of a multi-height row, composite logic cell 700 adjacent logic cells 100a and 100b. In this example, the height H2 of the multi-height row, composite logic cell 700 is double the height H1 of cells 100a and 100b. IC 800 can include any number of logic cells per row, and any number of rows. Centerlines (L) indicate the pitch between equally spaced adjacent power rails over the top edge of the logic cells 100a and 710, at the bottom edge of the logic cells 100b and 710, and between the logic cells 100a and 100b.

Comparing IC 800 of FIG. 8 to IC 600 of FIG. 6, the combined area occupied by cells 100a-100c and 400 of IC 600 is (W2−W1) larger than the combined area of cells 100a, 100b, and 700 in FIG. 8. That is, the structure shown in FIG. 8 has a smaller total area than the structure shown in FIG. 6 for the same logic functions being implemented. In one example, the height H2 of the multi-height row, composite logic cell 700 is twice the H1 (the height of logic cells 100, 300, and 400. In general, H2 is an integer multiple (two or more) of H1.

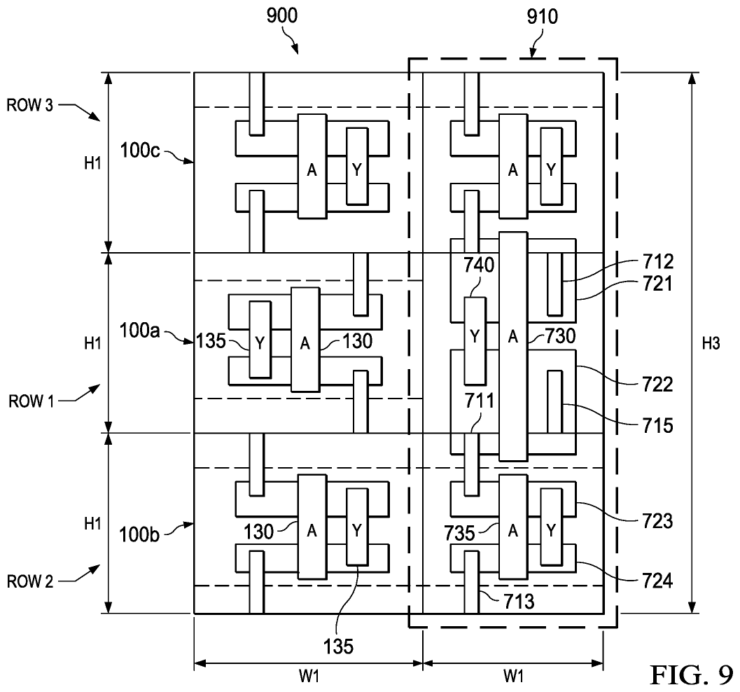

FIG. 9 shows an example of an IC 900 for a multi-height row, composite logic cell that has a height that is three-times H1, and spans three rows (ROW1, ROW2, and ROW3, with ROW3 being on the opposite of ROW1 as ROW2). Rows ROW1-ROW3 include logic cells 100a, 100b, and 100c, respectively. IC 900 also includes an instance of a multi-height row, composite logic cell 910 adjacent logic cells 100a-100c. In this example, the height H3 of the multi-height row, composite logic cell 910 is triple the height H1 of cells 100a,100b, and 100c, and thus spans three rows. Composite cell 910 may include one, two, three, or more logic functions, such as those logic functions discussed above. Composite cell 910 includes any one or more of transistors, capacitors, diodes, resistors, etc., and connection elements as described herein. Centerlines (L) indicate the pitch between equally spaced adjacent power rails over the top edge of the logic cells 100c and 910, at the bottom edge of the logic cells 100b and 910, between the logic cells 100a and 100b, and between the logic cells 100b and 100c.

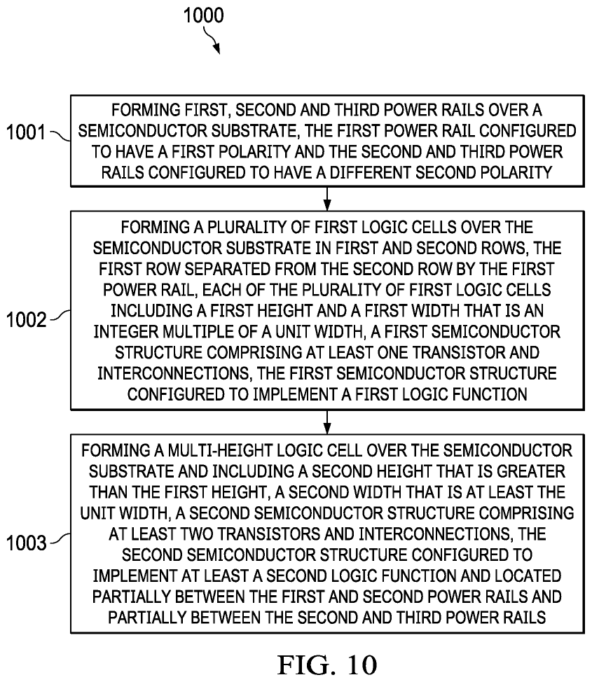

FIG. 10 is an example method 1000 for forming an integrated circuit in accordance with the disclosed embodiments. In this example, the method includes operations 1001, 1102, and 1003. Operation 1001 includes forming first, second and third power rails over a semiconductor substrate. The first power rail is configured to have a first polarity (e.g., VDD) and the second and third power rails configured to have a different second polarity (e.g., VSS).

At 1002, the method further includes forming a plurality of first logic cells (e.g., cells 100, 300) over the semiconductor substrate in first and second (or more) rows (e.g., ROW1 and ROW2). The first row is separated from the second row by the first power rail. Each of the plurality of first logic cells includes a first height and a first width. The first width is an integer multiple of a unit width. Each of the plurality of first logic cells also includes a first semiconductor structure that includes at least one transistor and interconnections. The first semiconductor structure is configured to implement a first logic function (e.g., inverter, NOR gate, NAND gate, etc.). For each first logic cell in the first row, the first structure is located entirely between the first and second power rails. For each first logic cell in the second row, the first structure is located entirely between the first and third power rails.

The method 1000 also includes forming (1103) a multi-height logic cell (e.g., cell 700) over the semiconductor substrate. The multi-height logic cell includes a second height that is greater than the first height. The multi-height logic cell has a second width that is at least the unit width. The multi-height logic cell also includes a second semiconductor structure that includes at least two transistors and interconnections. The second semiconductor structure is configured to implement at least a second logic function. The second semiconductor structure is located partially between the first and second power rails and partially between the second and third power rails.

In this description, the term “couple” may cover connections, communications, or signal paths that enable a functional relationship consistent with this description. For example, if device A generates a signal to control device B to perform an action: (a) in a first example, device A is coupled to device B by direct connection; or (b) in a second example, device A is coupled to device B through intervening component C if intervening component C does not alter the functional relationship between device A and device B, such that device B is controlled by device A via the control signal generated by device A.

A circuit or device that is described herein as including certain components may instead be adapted to be coupled to those components to form the described circuitry or device. For example, a structure described as including one or more semiconductor elements (such as transistors), one or more passive elements (such as resistors, capacitors, and/or inductors), and/or one or more sources (such as voltage and/or current sources) may instead include only the semiconductor elements within a single physical device (e.g., a semiconductor die and/or integrated circuit (IC) package) and may be adapted to be coupled to at least some of the passive elements and/or the sources to form the described structure either at a time of manufacture or after a time of manufacture, for example, by an end-user and/or a third-party.

While the use of particular transistors is described herein, other transistors (or equivalent devices) may be used instead. For example, a p-type metal-oxide-silicon field effect transistor (“MOSFET”) may be used in place of an n-type MOSFET with little or no changes to the circuit. Furthermore, other types of transistors may be used (such as bipolar junction transistors (BJTs)).

Uses of the phrase “ground” in the foregoing description include a chassis ground, an Earth ground, a floating ground, a virtual ground, a digital ground, a common ground, and/or any other form of ground connection applicable to, or suitable for, the teachings of this description. Unless otherwise stated, “about,” “approximately,” or “substantially” preceding a value means +/−10 percent of the stated value. Modifications are possible in the described examples, and other examples are possible within the scope of the claims.

Modifications are possible in the described embodiments, and other embodiments are possible, within the scope of the claims.

What is claimed is:

1. An integrated circuit (IC), comprising:
first, second and third power rails located over a semiconductor substrate, the first power rail configured to have a first polarity and the second and third power rails configured to have a different second polarity, and the first, second and third power rails located along corresponding first, second and third centerlines spaced apart by a same distance;
a plurality of first logic cells arranged over the semiconductor substrate in first and second rows, the first row separated from the second row by the first centerline, each of the plurality of first logic cells including a first height and a first width that is an integer multiple of a unit width, and a first semiconductor structure comprising at least two transistors and interconnections, and
for each first logic cell in the first row, the first semiconductor structure is located entirely between the first and second center lines, and
for each first logic cell in the second row, the first semiconductor structure is located entirely between the first and third center lines; and
a multi-height logic cell arranged over the semiconductor substrate and including:
a second height that is greater than the first height,
a second width that is at least the unit width,
a second semiconductor structure comprising at least two transistors and interconnections, the second semiconductor structure located partially between the first and second centerlines and partially between the first and third centerlines.

2. The IC of claim 1, in which the second height is an integer multiple of the first height.

3. The IC of claim 1, in which the second height is twice the first height.

4. The IC of claim 1, in which the second height is three-times the first height.

5. The IC of claim 1, in which the second width equals the unit width.

6. The IC of claim 1, in which the second width is different from the first width.

7. The IC of claim 1, in which the multi-height logic cell includes a third semiconductor structure, the third semiconductor structure is configured to implement a third logic function.

8. The IC of claim 7, in which:
the first semiconductor structure is configured to implement a first drive strength; and
the second semiconductor structure is configured to implement a different second drive strength.

9. The IC of claim 7, in which the second logic function is configured to have a lower propagation delay than the third logic function.

10. The IC of claim 7, in which the third semiconductor structure is located entirely between the first and third centerlines.

11. The IC of claim 1, in which the second logic function is at least one of an inverter, a NAND gate, and a NOR gate.

12. An integrated circuit (IC), comprising:
first, second and third power rails located over a semiconductor substrate, the first power rail configured to have a first polarity and the second and third power rails configured to have a different second polarity, and the first, second and third power rails located along corresponding first, second and third centerlines spaced apart by a same distance;
a plurality of first logic cells arranged over the semiconductor substrate in first and second rows, the first row separated from the second row by the first centerline, each of the plurality of first logic cells including a first height and a first width that is an integer multiple of a unit width and logic gate components, and
for each first logic cell in the first row, the corresponding logic gate components are located entirely between the first and second centerlines, and
for each first logic cell in the second row, the corresponding logic gate components are located entirely between the first and third centerlines; and
a multi-height logic cell arranged over the semiconductor substrate and including:
a second height that is an integer multiple of the first height, the integer being two or greater,
corresponding logic gate components that are located partially between the first and second centerlines and partially between the second and third centerlines.

13. The IC of claim 12, in which the logic gate components of the multi-height logic cell are configured to provide a higher drive strength than the logic gate components of at least some of the first logic cells.

14. The IC of claim 12, in which the logic gate components of the multi-height logic cell are located entirely between the first and third centerlines.

15. The IC of claim 12, in which the logic gate components of the multi-height logic cell are configured to implement at least one of an inverter, a NAND gate, and a NOR gate.

16. A method of forming an integrated circuit (IC), comprising:
forming first, second and third power rails over a semiconductor substrate, the first power rail configured to have a first polarity and the second and third power rails configured to have a different second polarity, and the first, second and third power rails located along corresponding first, second and third centerlines spaced apart by a same distance;
forming a plurality of first logic cells over the semiconductor substrate in first and second rows, the first row separated from the second row by the first centerline, each of the plurality of first logic cells including a first height and a first width that is an integer multiple of a unit width, a first semiconductor structure comprising at least one transistor and interconnections, the first semiconductor structure, for each first logic cell in the first row, the first structure is located entirely between the first and second centerlines, and for each first logic cell in the second row, the first structure is located entirely between the first and third centerlines; and
forming a multi-height logic cell over the semiconductor substrate and including a second height that is greater than the first height, a second width that is at least the unit width, a second semiconductor structure comprising at least one transistor and interconnections, the second semiconductor structure located partially between the first and second centerlines and partially between the second and third centerlines.

17. The method of claim 16, wherein:
forming the multi-height logic cell comprises forming the multi-height logic cell to have a first current drive strength; and
forming the plurality of first logic cells comprises at least one of the first logic cells to have a different second drive strength.

18. The method of claim 16, in which forming the multi-height logic cell to have the second height that is greater than the first height comprises forming the multi-height logic cell to have a second height that is an integer multiple of the first height, in which the multiple is at least 2.

19. The method of claim 16, in which forming the multi-height logic cell includes forming the multi-height logic cell to include a third semiconductor structure, the third semiconductor structure configured to implement a logic function different from that implemented by the first logic function.

20. The method of claim 19, in which the third semiconductor structure is located entirely between the first and third centerlines.
